(19) United States
(12) Patent Application Publication
(10) Pub. No.: US 2021/0305325 A1
(43) Pub. Date: Sep. 30, 2021

(54) DISPLAY DEVICE

(71) Applicant: Japan Display Inc., Tokyo (JP)

(72) Inventor: Masakazu GUNJI, Minato-ku (JP)

(73) Assignee: Japan Display Inc., Tokyo (JP)

(21) Appl. No.: 17/214,997

(22) Filed: Mar. 29, 2021

(30) Foreign Application Priority Data
Mar. 30, 2020 (JP) 2020-060469

(51) Int. Cl. H01L 27/32

(52) U.S. Cl. CPC H01L 27/322; H01L 27/3246

(57) ABSTRACT

A display device comprising: a plurality of pixels P; convex portion rows, composed by a plurality of convex portions 50 spaced from each other, formed on a boundary between adjacent pixels P in the plurality of pixels P; color filters CF, wherein a color filter CF formed on one side of a convex portion row has a different color from that of a color filter CF formed on the other side of the convex portion row.

### CROSS-REFERENCE TO RELATED APPLICATION

The present application claims priority from Japanese application JP 2020-060469 filed on Mar. 30, 2020, the content of which is hereby incorporated by reference into this application.

### BACKGROUND OF THE INVENTION

### 1. Field of the Invention

The present invention relates to display devices, particularly to, organic electroluminescence (EL) display devices.

### 2. Description of the Related Art

Organic EL elements have attracted much attention as a thin and light-weight light emitting source, and organic EL display devices where organic light-emitting diodes (OLEDs) which are organic EL elements are arranged in each of a plurality of pixels arranged two-dimensionally in a display region have been developed.

In the related art, in such an organic EL display device, pixel electrodes separated for each pixel are formed on a substrate made of glass or the like. A bank for partitioning the pixel is formed along an edge of the pixel electrode, and after that, an organic material layer including a light emitting layer and a counter electrode are formed by staking on the pixel electrode and the bank, so that an OLED configured with the pixel electrode, the organic material layer, and the counter electrode is manufactured.

In addition, as an organic EL display device for color display, an organic EL display device with a structure in which light emitting layers having different emission colors for each color, for example, red (R), green (G), blue (B), and the like are formed by coating or the like in a so-called separate coating method and an organic EL display device with a structure (referred to as a color filter method) in which an organic EL element that emits light that can be regarded as white light is combined with a color filter have been developed.

Among these organic EL display devices, in a case of aiming for high definition of an image in the separate-coating-type organic EL display device, since the pixel is miniaturized to reduce the pixel pitch, it is difficult to form a light emitting layer for each pixel. For this reason, it has been pointed out that it is difficult to achieve the high definition of the pixel by the separate coating method.

In contrast, it has been considered that, since it is not necessary to separately form a light emitting layer for each pixel, the color-filter-type organic EL display device is advantageous for the high definition. That is, in this case, the organic material layer including the light emitting layer may be formed with the same layer structure over the entire display region, and the color of the light emitted from each pixel may be adjusted by the color filter, so that the pixel is easily miniaturized in terms of manufacturing.

The color-filter-type organic EL display device is manufactured by a method of forming a substrate on which a color filter separately from a substrate on which a white light emitting OLED is formed and pasting the substrates together. It has also been proposed to manufacture the color-filter-type organic EL display device by a method of further forming a color filter on a substrate on which a white light emitting OLED is formed. JP 2002-243932 A discloses a method for manufacturing a color filter by an inkjet method. In addition, JP 2015-204237 A discloses a configuration in which a colored film constituting a color filter is buried in a concave region for each pixel generated by a bank.

In the display device including the above-mentioned color filter, with the high definition thereof, it has become difficult to partition a black matrix and pattern a color filter. In addition, even in a case where a color filter is formed on an OLED by an inkjet method, there is a problem that a high-definition patterning technique is required for the formation thereof.

### SUMMARY OF THE INVENTION

An object of the present invention is to provide a high-definition display device including a color filter.

A display device according to the present invention is a display device including: a plurality of pixels; convex portion rows, composed by a plurality of convex portions spaced from each other, formed on a boundary between adjacent pixels in the plurality of pixels; color filters, wherein a color filter formed on one side of a convex portion row has a different color from that of a color filter formed on the other side of the convex portion row.

### BRIEF DESCRIPTION OF THE DRAWINGS

FIG. 1 is a schematic plan view of an organic EL display device according to an embodiment of the present invention;

FIG. 2 is a schematic cross-sectional view of the organic EL display device taken along a cut line II-II of FIG. 1;

FIG. 3 is a schematic view illustrating a structure of a color filter formed with a convex portion row as a boundary;

FIG. 4 is a schematic view illustrating a structure of a color filter formed with a convex portion row as a boundary;

FIG. 5 is a schematic plan view illustrating a first modified example of an arrangement pattern of convex portions in the convex portion row;

FIG. 6 is a schematic plan view illustrating a second modified example of the arrangement pattern of the convex portions in the convex portion row; and

FIG. 7 is a schematic plan view illustrating a third modified example of the arrangement pattern of the convex portions in the convex portion row.

### DETAILED DESCRIPTION OF THE INVENTION

Hereinafter, an organic EL display device according to the embodiment will be described with reference to the drawings by exemplifying an organic EL display device 1. It is noted that the drawings referred to in the following description may be illustrated by enlarging characterized portions for the convenience in order to make the characteristics easier to understand, and the dimensional ratio of each component is not always limited to the same as the actual one. In addition, the materials and the like exemplified in the following description are examples, and each component may be different from that having the exemplified materials, and the present invention can be implemented by being changed within a range without changing the spirit of the present invention.

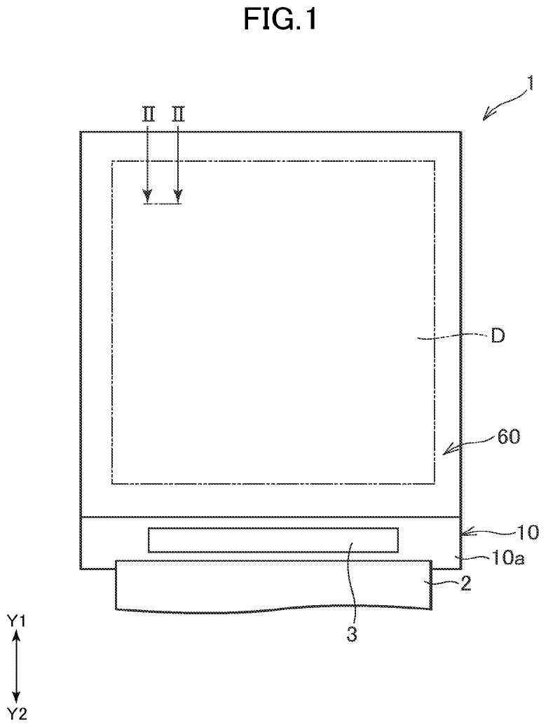

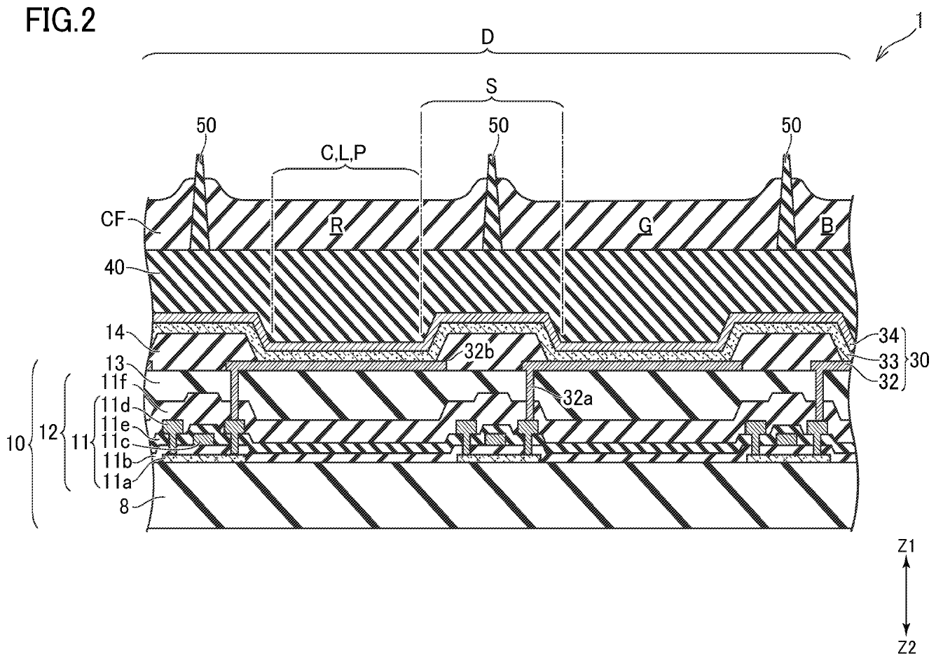

FIG. 1 is a schematic plan view of the organic EL display device 1 according to an embodiment of the present invention, and FIG. 2 is a schematic cross-sectional view taken along a cut line II-II of the organic EL display device 1 illustrated in FIG. 1. It is noted that, for the convenience of explanation of the embodiment, a positional relationship of each component will be described using coordinates of a Y-axis (Y1 direction, Y2 direction) and a Z-axis (Z1 direction, Z2 direction).

As illustrated in FIG. 1, the organic EL display device 1 has a TFT substrate 10 having a rectangular display region D and a counter substrate 60. A shape of the TFT substrate 10 in a plan view is smaller than a shape of the counter substrate 60 in a plan view, and an upper surface 10a of a portion (a portion on the Y2 direction side) of the TFT substrate 10 is exposed without being covered with the counter substrate 60. A flexible wiring board 2 and a driver integrated circuit (IC) 3 are connected to the upper surface 10a.

Next, details of a configuration of the display region D of the organic EL display device 1 will be described. As illustrated in FIG. 2, a plurality of pixels P are arranged in a matrix shape in the TFT substrate 10 as the display region D.

The TFT substrate 10 has an insulating substrate 8, a thin film transistor 11, a circuit layer 12 on which electrical wiring (not illustrated) is formed, and a planarization film 13. A structure including an organic EL light emitting element 30 and a color filter CF is provided on the TFT substrate 10. The structure includes the organic EL light emitting element 30, a planarization layer 40, a convex portion 50, and the color filter CF.

The circuit layer 12 is a layer formed on the insulating substrate 8 for driving the organic EL light emitting element 30. The thin film transistor 11, a passivation film 11f, and the electrical wiring (not illustrated) are formed in the circuit layer 12.

The thin film transistor 11 is provided on the substrate 10 for each pixel P. Specifically, the thin film transistor 11 is configured with, for example, a polysilicon semiconductor layer 11a, a gate insulating layer 11b, a gate electrode 11c, a source/drain electrode 11d, and a first insulating film 11e. The thin film transistor 11 is covered with the passivation film 11f which is an insulating film protecting the thin film transistor 11.

The planarization film 13 is formed to cover the circuit layer 12. The planarization film 13 is a layer made of an insulating material and is formed between the circuit layer 12 and the organic EL light emitting element 30 so that electrical insulation can be formed between the adjacent thin film transistors 11 and between the thin film transistor 11 and the organic EL light emitting element 30. The planarization film 13 is made of, for example, a material such as SiO₂, SiN, acrylic, or polyimide.

A reflective film (not illustrated) made of a metal film may be formed in the region corresponding to each pixel P on the planarization film 13. By providing the reflective film, the light emitted from the organic EL light emitting element 30 is reflected toward the counter substrate 60 side.

A plurality of the organic EL light emitting elements 30 are individually formed for each pixel P on the planarization film 13 (on the TFT substrate 10). The organic EL light emitting element 30 has a pixel electrode (anode) 32, an organic material layer 33 having at least a light emitting layer, and a counter electrode (cathode) 34 formed to cover the organic material layer 33. A region where the pixel electrode 32, the organic material layer 33, and the counter electrode 34 overlap each other functions as a light emitting region L.

The pixel electrode 32 is an electrode that injects a driving current into the organic material layer 33. The pixel electrode 32 is connected to a contact hole 32a, and thus, the pixel electrode is electrically connected to the thin film transistor 11 to supply a driving current.

The pixel electrode 32 is made of a conductive material. Specifically, the material of the pixel electrode 32 may be a material having translucency and conductivity, for example, not only a composite oxide such as indium tin oxide (ITO), but indium zinc composite oxide (IZO), tin oxide, zinc oxide, indium oxide, or aluminum oxide. It is noted that, as long as the reflective film is made of a metal such as silver and is in contact with the pixel electrode 32, the pixel electrode 32 may have translucency. In such a configuration, the reflective film becomes a portion of the pixel electrode 32.

A pixel separation film 14 is formed to partition the adjacent pixel electrodes 32 from each other along the boundary between the pixels P. The pixel separation film 14 is a so-called bank. The pixel separation film 14 has a function of preventing contact between the adjacent pixel electrodes 32 and preventing a leakage current between the pixel electrode 32 and the counter electrode 34.

In the embodiment, the pixel separation film 14 covers an outer end 32b of the pixel electrode 32 and projects upward (Z1 direction side in the figure). Accordingly, a surface having a concave-convex shape is configured with the upper surface of the pixel separation film 14 (the surface on the Z1 direction side) and the upper surface of the pixel electrode 32.

The pixel separation film 14 covers the outer end 32b of the pixel electrode 32 and exposes a region corresponding to the light emitting region L of the pixel electrode 32. The pixel separation film 14 is made of an insulating material, specifically, for example, a photosensitive resin composition.

It is noted that, in the embodiment, the region corresponding to the exposed pixel electrode 32 is formed as a concave region C, and the region on the pixel separation film 14 is formed as a convex region S. It is noted that, the concave region C corresponds to the light emitting region L.

The organic material layer 33 has a stacked structure formed of an organic material and includes a light emitting layer. The organic material layer 33 is formed by stacking, for example, a hole injection layer, a hole transport layer, a light emitting layer, an electron transport layer, and an electron injection layer (not illustrated) in this order from the pixel electrode 32 side. It is noted that the stacked structure of the organic material layer 33 is not limited to the described herein, and the stacked structure is not specified as long as the stacked structure includes at least a light emitting layer.

The organic material layer 33 (light emitting layer) is formed to cover the exposed pixel electrode 32 (the region of the pixel electrode 32 corresponding to the light emitting region L) and the pixel separation film 14. It is noted that, in the embodiment, emission color of the light emitting layer is white, but other colors may be used.

The light emitting layer is configured with, for example, an organic EL material that emits light when holes and electrons are coupled. Such an organic EL material may be, for example, a material generally used as an organic light emitting material.

The counter electrode 34 is formed to cover the organic material layer 33 (on the light emitting layer) and the pixel separation film 14. In the embodiment, the counter electrode 34 is not independent for each pixel P and is formed to cover the entire region in which the pixels P of the display region D are arranged. With such a configuration, the counter electrode 34 is commonly in contact with the organic material layers 33 of the plurality of organic EL light emitting elements 30.

The counter electrode 34 is made of a material having translucency and conductivity. Specifically, the material of the counter electrode 34 is preferably, for example, ITO, but a mixture of a metal such as silver or magnesium to a conductive metal oxide such as ITO or InZnO or a stack of a metal thin film of silver, magnesium or the like and a conductive metal oxide may be used.

The upper surface of the counter electrode 34 is covered with the planarization layer 40 over the plurality of pixels P. The planarization layer 40 has a function as a planarization film for planarizing the surface thereof in addition to a function as a sealing film for preventing oxygen and moisture from entering each layer including the organic material layer 33. Specifically, as described above, with the formation of the pixel separation film 14, a concave-convex shape basically occurs on the surface of the structure on the TFT substrate 10, and the upper surface of the counter electrode 34 also has a concave-convex shape, so that the planarization film 45 planarizes the concave-convex shape. The planarization layer 40 may be a single layer or may be configured with a plurality of layers. The planarization layer 40 is basically made of a transparent material and is furthermore made of a material that achieves the above-mentioned functions. It is noted that the material of the planarization layer 40 may be any one of an inorganic material and an organic material, and in the case of a multilayer structure, both layers may be included.

The convex portion 50 is formed on the surface of the planarization layer 40. The convex portion 50 is formed on the boundary between pixels adjacent to each other on the surface of the planarization layer 40. The shape of the convex portion 50 is, for example, a cylinder or a frustum, and a plurality of convex portions 50 are arranged in a direction along the boundary and are spaced from each other to form a convex portion row. In the embodiment, the pixel separation film 14 is formed along the boundary between the pixels, and the convex portion 50 (convex portion row) is formed in the region where the pixel separation film 14 is arranged in a plan view. By the way, in FIG. 2, the convex portions 50 are arranged in a direction perpendicular to the paper surface to form the convex portion row.

In addition, the color filter CF is stacked on the surface of the planarization layer 40. In the embodiment, the color filter CF has colored films R, G, and B colored in a plurality of colors such as red, green, and blue. The colored films R, G, and B are films that allow light from the organic EL light emitting element 30 to pass through, and are made of, for example, a resin colored with a pigment. Specifically, a material for resist can be used as the resin, and particularly, a color resist is provided for a color filter.

Herein, the convex portion 50 or the convex portion row has a function as a boundary for partitioning the color filter CF. The color filter CF has a thickness of, for example, several microns, and the height of the convex portion 50 is a height required to partition the color filter CF having the thickness, so that the height is basically set to a value that exceeds the thickness of the color filter CF. In addition, basically, the color filter CF on one side of the convex portion row has a different color from that of the color filter CF on the other side of the convex portion row.

The convex portion 50 can be formed, for example, by etching a film of a resin or the like stacked on the surface of the planarization layer 40 by using a photolithography technique. The colored films R, G, and B constituting the color filter CF are formed by dropping a liquid material such as a resin onto the planarization layer 40 by an inkjet method and curing the material with heat, ultraviolet rays, or the like. In the embodiment, color resist is used as a liquid material for the color filter CF. The color resist dropped on a certain pixel P is prevented from flowing out to adjacent other pixels P by the convex portion row arranged on the edge of the pixel P.

It is noted that a protective film, the counter substrate 60, and the like may be formed on the color filter CF, but the protective film, the counter substrate 60, and the like are not illustrated in FIG. 2.

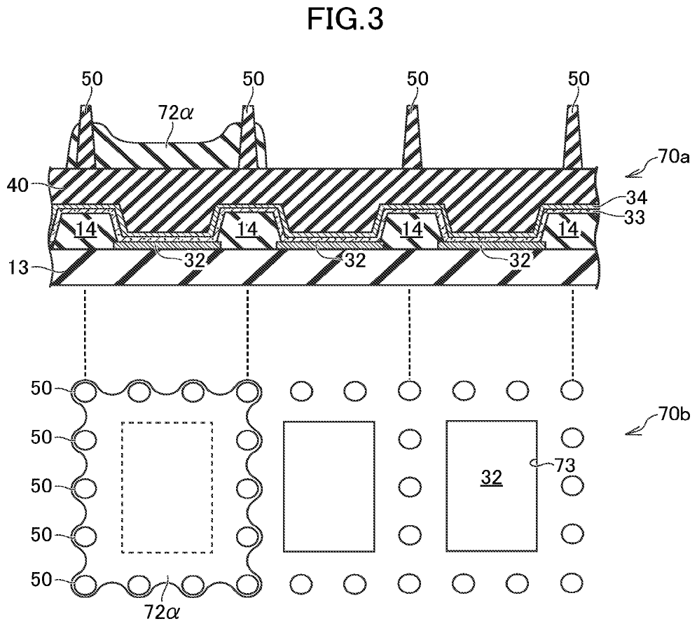

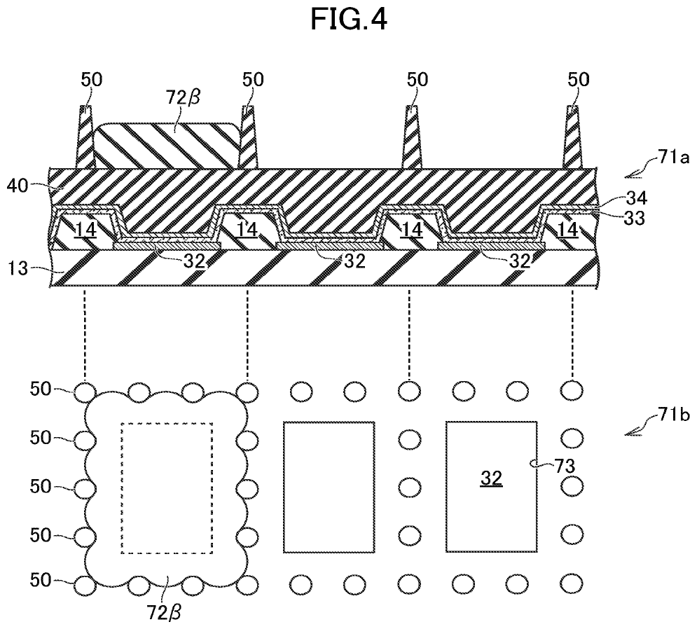

FIGS. 3 and 4 are schematic views illustrating the structure of the color filter CF formed with the convex portion row as a boundary, respectively, and illustrate a vertical cross-sectional view in a region near the cut line II-II of FIG. 1 and a plan view at a position corresponding to the cross-sectional view. FIGS. 3 and 4 illustrate a state in which only one of the colored films R, G, and B of the color filter CF is formed. Specifically, a cross-sectional view 70a of FIG. 3 and a cross-sectional view 71a of FIG. 4 illustrate a simplified structure above the planarization film 13 of FIG. 2, and the cross-sectional views illustrate the planarization film 13, the pixel electrode 32, the pixel separation film 14, the organic material layer 33, the counter electrode 34, the planarization layer 40, the convex portion 50, and a color resist 72 (72α, 72β). In addition, in a plan view 70b of FIG. 3 and a plan view 71b of FIG. 4, an opening portion 73 and the convex portion 50 of the pixel are illustrated. The rectangular opening portion 73 corresponds to the opening of the pixel separation film 14, and the inside thereof is the pixel electrode 32 exposed in the opening of the pixel separation film 14. That is, the outside of the opening portion 73 is the region on the pixel separation film 14, that is, the above-mentioned convex region S, and the inside thereof is the above-mentioned concave region C. The convex portion 50 is formed on the pixel separation film 14, and FIGS. 3 and 4 illustrate an example in which the convex portions 50 are arranged in a rectangular shape around the opening portion 73. The three opening portions 73 arranged in the lateral direction correspond to the pixels having different colors, for example, the pixels corresponding to the colored films R, G, and B from the left side, and the color resist 72 illustrated corresponds to the colored film R.

FIG. 3 and FIG. 4 illustrate a case where the wettability of the convex portion 50 with respect to the liquid color resist 72 is different. Specifically, FIG. 3 illustrates a case where the wettability is high, and FIG. 4 illustrates a case where the wettability is low.

The color resist 72 dropped onto the planarization layer 40 spreads along the surface of the planarization layer 40 and reaches the convex portion 50. As illustrated in FIG. 3, the color resist 72a in the case where the wettability of the convex portion 50 is increased enters into the gap of the convex portion row as a result of trying to increase the contact area with the convex portion 50, and the color resist 72a exhibits the behavior of climbing the convex portion 50 upward. Accordingly, even if the dropped amount of the color resist 72a is large, the color resist 72a is less likely to flow out to the adjacent pixel.

On the other hand, as illustrated in FIG. 4, the color resist 720 in the case where the wettability of the convex portion 50 is decreased is repelled by the convex portion row while being barely inserted in the gap between the convex portion rows, and as a result, it is difficult for the color resist 723 to flow out to the adjacent pixels.

By providing the convex portion row at the boundary of the forming region of the colored film in this manner, the gap between the convex portion rows functions as a buffer against the excess of discharge of the color resist 72 and prevents the color resist 72 from flowing out to the adjacent pixels. Therefore, by the function of the convex portion 50 or the convex portion row, the variation in the thickness of the colored film due to the variation in the amount of discharge of the color resist 72 is suppressed, and the high-definition patterning of the color filter CF is possible. In addition, since a wall such as a black matrix is not required, an aperture ratio of the color filter CF can be improved.

The function of the convex portion 50 described above can be adjusted by the shape or size of the convex portion 50 and by the space in the convex portion row, in addition to the wettability of the convex portion 50. Furthermore, the wettability of the surface of the planarization layer 40 may also affect the prevention of outflow of the color resist 72 from the gaps in the convex portion rows. Therefore, in addition to the wettability of the planarization layer 40, the adjustment can be preferably performed. By the way, the wettability can be controlled, for example, by selecting the materials of the convex portion 50 and the planarization layer 40 or by selecting the solvent of the color resist 72. For example, in a case where all the convex portion 50, the planarization layer 40, and the color resist 72 are hydrophilic or hydrophobic, the wettability can be heightened, and conversely, in a case where one is hydrophilic and the other is hydrophobic, the wettability can be lowered. It is noted that a material such as a transparent material other than black can be applied to the convex portion 50, and the range of material selection is widened.

In the plan views 70b and 71b of FIGS. 3 and 4, the convex portion rows are provided along all four sides of the rectangle of the opening portion 73, but basically, the convex portion rows may be satisfactorily provided between the adjacent pixels where the colored films having different colors are arranged. Therefore, for example, in a stripe arrangement in which the pixels having the same color are arranged in the longitudinal direction, the convex portion rows between the pixels adjacent in the longitudinal direction can be omitted.

### Modified Example

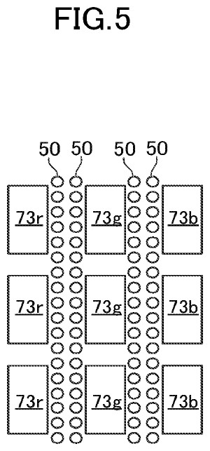

FIGS. 5 to 7 are schematic plan views illustrating modified examples of the arrangement pattern of the convex portions 50 in the convex portion row, respectively. It is noted that FIGS. 5 to 7 illustrate examples in which the R, G, and B pixels provided with the colored films R, G, B are arranged in a stripe in the longitudinal direction, and the convex portions 50 are provided only between the pixels adjacent to each other in the lateral direction, so that the convex portion rows extend in the longitudinal direction.

In a first modified example illustrated in FIG. 5, two rows of the convex portion rows are arranged at the boundary between the pixels having different colors. For example, a plurality of pairs of the convex portions configured with the two convex portions 50 arranged in the lateral direction are arranged in the longitudinal direction on the pixel separation film between an opening portion 73r of the R pixel and an opening portion 73g of the G pixel, so that a double arrangement of the convex portion rows is configured. Similarly, a double arrangement of the convex portion rows is provided between the opening portion 73g of the G pixel and an opening portion 73b of the B pixel. In addition, although not illustrated in the figure, the opening portion 73b of the B pixel and the opening portion 73r of the R pixel are adjacent to each other in the lateral direction, and similarly, a double arrangement of the convex portion rows is also provided between the openings.

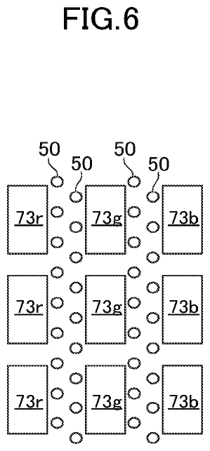

In a second modified example illustrated in FIG. 6, the convex portions are arranged in a zigzag manner at the boundary between the pixels each has a different color from the other. For example, the two convex portion rows with the convex portions 50 spaced by the same distance from each other in the longitudinal direction are arranged in parallel on the pixel separation film between the opening portion 73r of the R pixel and the opening portion 73g of the G pixel, with their positions in the longitudinal direction are shifted by half the distance, to configure the convex portion rows in which the convex portions 50 are arranged alternately. Similarly, the convex portion rows in a zigzag arrangement are provided between the opening portion 73g of the G pixel and the opening portion 73b of the B pixel. In addition, although not illustrated in the figure, similarly, the convex portion rows in a zigzag arrangement are provided between the opening portion 73b of the B pixel and the opening portion 73r of the R pixel.

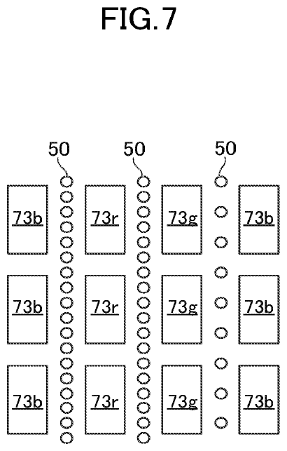

In a third modified example illustrated in FIG. 7, the space between the convex portions 50 in the convex portion row differs depending on the color combination of the colored films on both sides of the convex portion row. The space can be changed, for example, according to the spreadability of the color resist 72 provided in the pixels adjacent to the convex portion row to the near pixels. For example, in a case where the color resist 72 dropping onto the R pixel among the R, G, and B pixels is most likely to spread, as illustrated in FIG. 7, the space in the convex portion row between the R pixel and the B pixel or between the R pixel and the G pixel can be narrower than the space in the convex portion row between the G pixel and the B pixel.

In addition, the space may be further changed according to the difference in the spreadability of the color resist 72 dropped onto the pixels on both sides of the convex portion row. For example, in a case where the spreadability of the color resist 72 of the B pixel to the R pixel is smaller than spreadability of the color resist 72 of the G pixel to the R pixel and the difference in spreadability between the B pixel and the R pixel is larger than that between the G pixel and the R pixel, the space in the convex portion row between the R pixel and the B pixel becomes narrower than the space in the convex portion row between the G pixel and the R pixel, so that the outflow of the color resist 72 from the R pixel to the B pixel can be more preferably prevented.

It is noted that, in the embodiments and modified examples described above, an example in which an organic EL element exhibiting white color is used as the light emitting element has been illustrated, but the present invention is not limited thereto, and a light emitting diode (QLED) using quantum dots can also be combined. Furthermore, not only in a self-luminous element, but also in electronic paper using, for example, an electrophoresis material, the color filter may be formed by using the planarization layer 40, the convex portion 50, and the color resist 72 described above on a layer on which the electrophoresis element is formed.

Heretofore, although the embodiments and modified examples of the present invention have been described, the present invention is not limited to the above-described embodiments and modified examples. For example, the configurations described in the above-described embodiments may be replaced with substantially the same configurations, configurations that exhibit the same functions and effects, or configurations that can achieve the same object.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a plurality of pixels;
convex portion rows, composed by a plurality of convex portions spaced from each other, formed on a boundary between adjacent pixels in the plurality of pixels;
color filters,
wherein a color filter formed on one side of a convex portion row has a different color from that of a color filter formed on the other side of the convex portion row.

2. The display device according to claim 1, further comprising a planarization film covering the plurality of pixels,
wherein the convex portion row is formed on the planarization film.

3. The display device according to claim 1, further comprising:
pixel electrodes individually formed for each pixel; and
a pixel separation film which exposes a portion of the pixel electrodes and is provided on the pixel electrodes to partition the adjacent pixels from each other,
wherein the convex portion row is formed in a region in which the pixel separation film is arranged in a plan view.

4. The display device according to claim 1, wherein two rows of the convex portion rows are arranged at the boundary between the pixels in a plan view.

5. The display device according to claim 1, wherein, in the convex portion row, the convex portions are arranged in a zigzag manner in a plan view.

6. The display device according to claim 1, wherein a space between the convex portions in the convex portion row differs depending on a color combination of the color filters on both sides of the convex portion row.
